(19) United States
(12) Patent Application Publication
(10) Pub. No.: US 2017/0038416 A1
(43) Pub. Date: Feb. 9, 2017

(54) SOLAR POWER GENERATION RATING SYSTEM

(71) Applicants: YASUTO KUSAKA, TOKYO (JP); MORIMITSU TACHIBANA, TOKYO (JP); Naotaka HOSHIKA, Ehime (JP)

(72) Inventors: NAOTAKA HOSHIKA, EHIME (JP); MORIMITSU TACHIBANA, TOKYO (JP)

(21) Appl. No.: 15/102,036

(22) PCT Filed: Dec. 6, 2013
(86) PCT No.: PCT/JP2013/007212

§ 371 Date: Sep. 14, 2016

(51) Int. Cl. G01R 21/133; H02S 50/00

(52) U.S. Cl. CPC G01R 21/133; H02S 50/00

(57) ABSTRACT

A solar power generation rating system compares amount of electrical energy generated by a solar power generating apparatus and amount of electricity used, rates whether environmentally friendly use of privately generated electricity is being performed, and allocates points to a user. The system includes a portable terminal having a small solar panel to generate solar power, an electrical energy accumulator, a consumed electrical energy detection and memory unit and a communication unit. The consumed electrical energy detection and memory unit detects the state of use of electrical energy and used electrical energy. The communication unit establishes communication with the rating server, and the rating server includes a receiver and a point allocator to compare the amount of electrical energy generated, state of use and used electrical energy. The rating server performs rating processing in accordance with comparison results, and allocates points.

### TECHNICAL FIELD

The present invention relates to a solar power generation rating system for evaluating power generation by a solar power generating apparatus against a set standard and assigning a rating and relates particularly to a solar power generation rating system for, based on amount of electrical energy generated by a user's power generating apparatus and amount of electrical energy used, rating whether electrical energy is being used in an environmentally friendly manner and allocating points to the user.

### BACKGROUND ART

A broad range of solar power generation technologies have been proposed and aggressively integrated into effectively implemented systems. Particularly noteworthy is the development of systems that actively promote utilization of electrical energy obtained by solar power generation, evaluate positive use of clean energy in terms of social impact, numerically quantify the same, assign and grant special benefits based on evaluation result points accrued in association with the allocation of points (marks), thereby promoting energy conservation by reducing fossil fuel consumption through positive use of clean energy.

For example, JP2012-14503A discloses a technology that installs a solar power generating apparatus for generating electrical energy (created energy) at a housing complex occupied by multiple residents, calculates predetermined points corresponding to a price of electrical energy generated by the solar power generating apparatus, and records them on stored energy point cards possessed by, inter alia, the residents, and suggests that it is possible to make refunds in the form of points with respect to created energy continuously produced at the housing complex.

Further, a technology for effective utilization of a low CO₂ emission power generation facility by having electrical energy customers themselves select time zones when CO₂ emission is low is disclosed in JP2010-28879A, wherein a monthly average base power consumption is calculated in advance and a power demand inducing system installed on the side of the power supplier computes time zones suitable for inducing power demand, whereafter such information is supplied to customers in advance to encourage them to make positive use of the low environmental impact power generation facility intentionally on their own, and eco-points are issued as a reward.

Moreover, JP2012-73867A teaches a technology in which a point management server unit uses a wireless communication unit to acquire data on purchased electrical energy, data on electrical energy generated by a solar power generation system and data on sold electrical energy that was generated by the solar power generation system and exported back to a public power grid, uses these different types of electrical energy data to calculate an amount of “eco-life” points that increases/decreases with increase/decrease of power self-sufficiency, and adds it to the members' eco-life point balance, and further suggests that this makes it possible to promote both alternative use of sustainable energy and energy conservation in good balance.

Of note here is that the systems adopting the aforesaid technologies are all ones that use solar panels installed on a building to generate solar power, so that installing a new installation can therefore be expected to involve huge costs, with the result that users would not necessarily feel they are getting a good deal in terms of satisfaction with earned points relative to equipment investment costs, and this has limited the ability to promote solar panel installation and maintain high user motivation to acquire points.

Furthermore, although systems that use the aforesaid technologies are conceivably focused on lowering power use time and/or cost, cases may arise in which consumption of power is minimized in order to accrue points, and since this would impact daily life, the ability to maintain user point-earning motivation at a high level has also been limited from this aspect.

In addition, the advantage of systems using the aforesaid technologies can be considered to increase with increasing amount of electrical energy generated, so that buildings or the like equipped with large-scale solar power generation systems are advantageous. However, use of such systems by individual users is hard to anticipate, and there has therefore been a problem of such systems becoming point earning system for heavy users.

Not only businesses but also individuals, both men and women of all ages, need to nurture an awareness of the need to reduce environmental impact. The question of how every person can efficiently utilize electrical energy is also a major issue from the viewpoint of energy resource depletion. The aforesaid technologies cannot necessarily be said to have been developed from such a viewpoint with the energy problem in mind and cannot be viewed as enabling participation in overcoming environmental issues at the individual level.

Therefore, development has been desired of a solar power generation rating system that enables electrical energy conservation and can in addition help sustain motivation by allocating points, and in which individuals can easily participate without incurring a significant economic burden or undue difficulty.

### PRIOR ART DOCUMENTS

### Patent Documents

Patent document 1: JP2012-14503A

Patent document 2: JP2010-28879A

Patent document 3: JP2012-73867A

### SUMMARY OF THE INVENTION

### Problems to be Overcome by the Invention

In order to overcome the aforesaid problems, the present invention provides a solar power generation rating system, which solar power generation rating system rates electrical energy generation by a portable small solar panel type solar power generating apparatus and which is particularly characterized in that it compares amount of electrical energy generated by a solar power generating apparatus and amount of power used, rates whether environmentally friendly use of privately generated electricity is being performed, and allocates points to a user.

### Means for Solving the Problem

In order to achieve the aforesaid object, the solar power generation rating system according to the present invention comprises: a portable terminal having a portable small solar panel for generating solar power, an electrical energy accumulator for storing electrical energy generated by the solar panel, a consumed electrical energy detection and memory unit for detecting amount of generated electrical energy stored in the electrical energy accumulator and used electrical energy signifying state of use, and a communication unit having transmit-receive capability for transmitting values measured by the consumed electrical energy detection and memory unit and used electrical energy to outside; and a rating server for receiving data from the portable terminal and performing rating processing, wherein the consumed electrical energy detection and memory unit comprises detection means for detecting state of use of electrical energy stored in the electrical energy accumulator and used electrical energy and memory means for sequentially storing amount of electrical energy generated by the solar panel, and state of use of electrical energy and used electrical energy detected by the detection means, the communication unit comprises communication means for establishing wired and/or wireless communication with the rating server after detection by the detection means and automatically transmitting amount of electrical energy generated data, state of electrical energy use data and electrical energy used data stored in the memory means, and the rating server comprises receive means for automatically receiving amount of electrical energy generated data, state of use data and electrical energy used data transmitted from the communication means, and point allocation means for comparing amount of electrical energy generated, state of use and used electrical energy, performing rating processing in accordance with comparison results, and allocating commensurate points.

In a further configuration, the point allocation means subtracts (electrical energy charged in the electrical energy accumulator obtained from the amount of electrical energy generated data) from (amount of electrical energy consumed by the portable terminal obtained from the electrical energy used data) and, in order to allocate higher points in proportion as the numerical value of the subtraction result is lower, weights it in proportion as the numerical value is lower, performs rating by calculating a sum or a product of the weighted value and the amount of electrical energy consumed whose resulting numerical value is defined as points, and allocates the points.

In still another configuration, the solar power generation rating system according to the present invention comprises: a portable small solar panel attached to a portable terminal for generating solar power, an electrical energy accumulator for storing electrical energy generated by the solar panel, a consumed electrical energy detection and memory unit for detecting amount of generated electrical energy stored in the electrical energy accumulator and amount of electrical energy used by the portable terminal, and a communication unit having transmit-receive capability for transmitting values measured by the consumed electrical energy detection and memory unit and amount of electrical energy used to outside, wherein a computer of the portable terminal automatically calculates amount of electrical energy generated and amount of electrical energy consumed, automatically judges following comparison processing whether the amount of electrical energy generated is enough to meet the amount of electrical energy consumed, and when the amount of electrical energy generated is greater than the amount of electrical energy consumed, uses the communication unit having transmit-receive capability to transmit an automatically calculated remaining amount of electrical energy to the rating server that communicates with the consumed electrical energy detection and memory unit.

### Effects of the Invention

Being configured in the manner described in detail in the foregoing, the present invention offers the following effects.

1. As the solar panel is small and portable, it can be purchased relatively inexpensively and attached to a tablet PC, mobile telephone, smartphone or other such portable terminal for power generation whenever and wherever. In other words, this means that countless small-scale solar power generating stations are spun off in place of a large-scale power generating station. Moreover, since the portable terminal is equipped with the consumed power detection and memory unit, easy mobility is enabled and detection of consumed electrical energy can be constantly performed. Further, amount of electrical energy generated data, state of electrical energy use data and electrical energy used data are sent to the rating server through the communication unit, so that the rating server can receive and analyze these data in real time. In addition, owing to the rating server being equipped with point allocation means, the server automatically performs rating processing in accordance with amount of electrical energy generated, state of use and used electrical energy, and allocates points, so that a user can automatically participate in overcoming environmental issues easily with no need for troublesome operations.

2. The point allocation means subtracts electrical energy charged in the electrical energy accumulator from amount of electrical energy consumed by the portable terminal and weights the resulting numerical value in proportion as the value is lower, and upon certifying as points a numerical value calculated as a sum or a product of the weighted value and the amount of electrical energy consumed, allocates points to the user, by which arrangement it becomes possible to make purchased electrical energy irrelevant and configure a system that targets overwhelming numerous small-scale terminals with priority on energy saving at the individual level.

3. The computer of the portable terminal automatically calculates and compares amount of electrical energy generated and amount of electrical energy consumed and automatically judges whether the amount of electrical energy generated is enough to meet the amount of electrical energy consumed, thereby enabling real time performance of the processing to be maintained at a high level. Further, when the amount of electrical energy generated is greater than the amount of electrical energy consumed, excess electrical energy is automatically evaluated by computer processing and sent to the rating server, so that network traffic is reduced and in addition the user becomes aware that the user's electrical energy consumption is consumption of earlier electrical energy and consumption of electrical energy other than from a public utility, and can easily participate in overcoming environmental issues simply by using the equipment, without conscious effort or performing special operations. In addition, since portable terminals are very mobile and their ownership rate is high, user participation in solving environmental problems is facilitated.

### BRIEF DESCRIPTION OF THE DRAWINGS

The solar power generation rating system according to the present invention is explained in detail below based on an embodiment shown in the drawings.

FIG. 1 is a schematic diagram of a solar power generation rating system in accordance with the present invention, and

FIG. 2 is a block diagram of the solar power generation rating system.

### BEST MODE FOR WORKING THE INVENTION

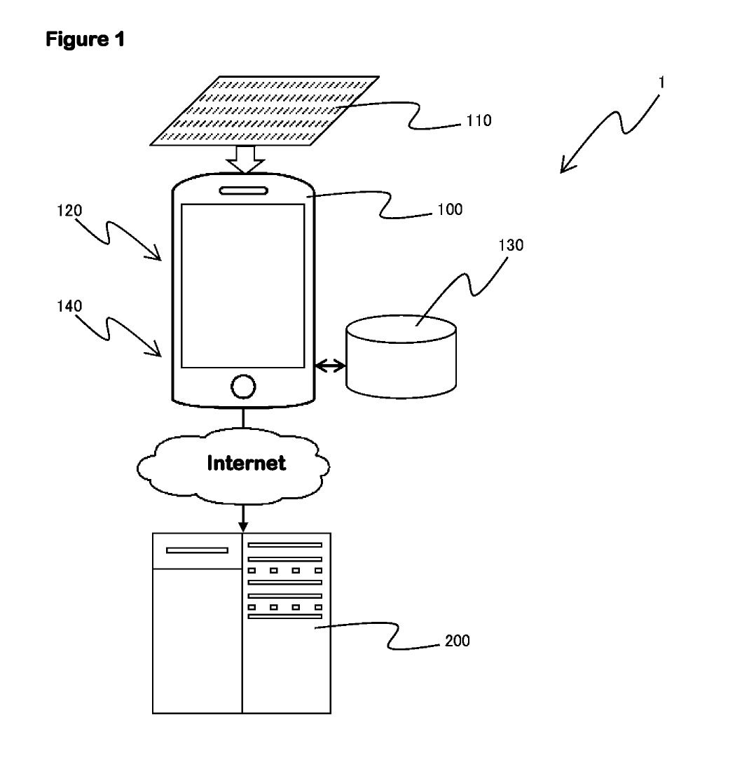

As shown in FIG. 1, a solar power generation rating system 1 according the present invention comprises a portable terminal 100 equipped with, inter alia, a solar panel 110 and a rating server 200 communicably interconnected through a network.

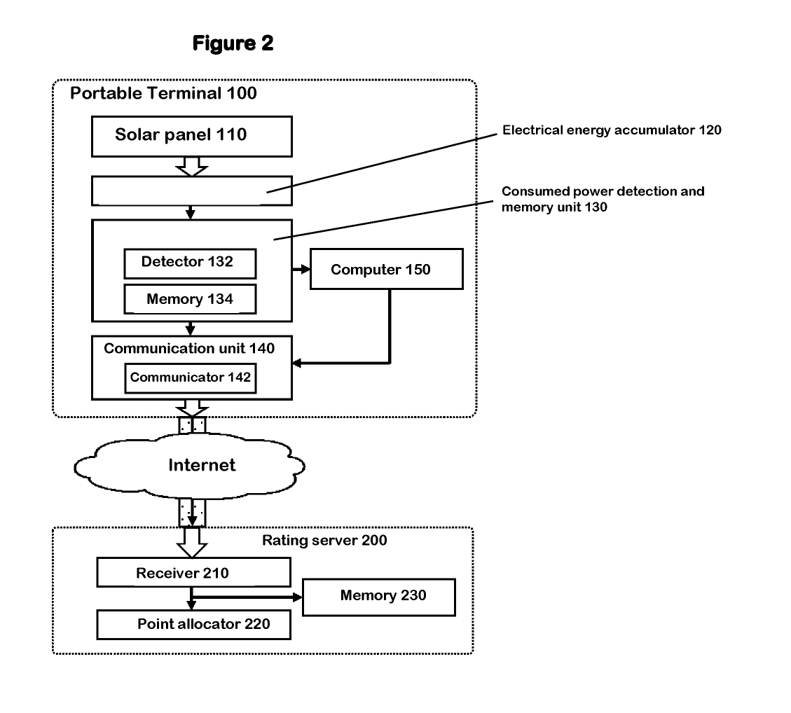

The portable terminal 100 is a portable small computer terminal equipped with communication capability and constituted as a tablet PC, mobile phone or smartphone, and as shown in FIGS. 1 and 2, comprises the solar panel 110, an electrical energy accumulator 120, a consumed power detection and memory unit 130, and a communication unit 140. The solar panel 110 is of a portable, small shape for performing solar power generation, and although it is integrally attached to the portable terminal in the present embodiment, it need not be an integrated unit but can alternatively be of a type detachably connected to the portable terminal through a separate USB port or the like. Moreover, while its output power is defined as about 0.3 W to 1.0 W in the present embodiment, it is not limited to this range and it is also possible to use a power generating apparatus of higher output or lower output.

The electrical energy accumulator 120 is a unit capable of storing electrical energy that is used to store mainly electricity generated by the solar panel 110. Although the electrical energy accumulator 120 can be one preinstalled in the portable terminal 100 as in the present embodiment, it is also possible in addition to the one preinstalled in the portable terminal 100 to additionally use a relatively large unit detachably connected to the portable terminal 100 for storing excess electrical energy. Further, an installed battery having a capacity of about 1 Ah to about 6 Ah is used in the present embodiment but the capacity is not limited to this range and an arrangement specifying installation of one of larger capacity is also possible.

The consumed power detection and memory unit 130 is a unit for detecting amount of electrical energy generated and state of use of the amount of electrical energy and is incorporated in the portable terminal 100 in the present embodiment. The amount of electrical energy generated by the solar panel 110 and stored in the electrical energy accumulator 120, and the state of use of electrical energy from the electrical energy accumulator 120 and the amount of used electrical energy are important parameters in the performance of rating processing by the rating server 200 explained below. The consumed power detection and memory unit 130 detects these data in real time.

As shown in detail in FIG. 2, the consumed power detection and memory unit 130 comprises detecting means 132 and memory means 134. The detecting means 132 is a unit for detecting state of use of electrical energy from the electrical energy accumulator 120 and amount of used electrical energy. This enables the amount of electrical energy generated and the amount consumed to be ascertained in detail in real time.

Further, the memory means 134 is a unit for sequentially storing data on amount of electrical energy generated by the solar panel 110, and state of use of electrical energy and amount of used electrical energy detected by the detecting means 132. Data on amount of electrical energy generated by the solar panel 110, acquired directly from the solar panel 110, and other data, acquired from the detecting means 132, are stored in the memory means 134. Although these data could instead be sequentially sent to the rating server 200 immediately after detection, this would increase consumption of electrical energy for data communication. It might also increase network traffic and cause communication failure. In the present embodiment, the aforesaid various data are stored in the memory means 134 and sent to the rating server 200 by the communication unit 140 (explained later) after passage of a specified time period, thereby avoiding electrical energy waste and network traffic congestion and thus enabling energy saving and stable operation.

The communication unit 140 is a device equipped with transmit-receive capability for sending data (measurement values) detected by the consumed power detection and memory unit 130 and data on amount of used electrical energy to the outside, and is incorporated in the portable terminal 100 in the present embodiment. Specifically, once the detecting means 132 has detected the various data (measurement values), the communication unit 140 establishes either or both of wireless communication and wired communication with the rating server 200. Then it automatically transmits amount of electrical energy generated data, electrical energy state of use data and electrical energy used data recorded in the memory means 134 to the rating server 200.

In the present embodiment, as stated above, the transmission of the various data by the communication unit 140 is timed to occur automatically upon passage of a specified time period after the detecting means 132 detects the data (measurement values), but this is not a limitation and, for example, the user can instead perform an operation to send the data whenever desired.

The rating server 200 is a server machine that communicates with the portable terminal 100 and is connected to the portable terminal 100 utilizing a wide area network such as the Internet. The rating server 200 is a server machine that rates users based on user power generation and state of use.

As shown in FIG. 2, the rating server 200 comprises receiving means 210 and point allocation means 220. The receiving means 210 is a means that automatically receives amount of electrical energy generated data, state of use data and electrical energy used data transmitted from the communication means 142 through the Internet. Although in the present embodiment the receiving means 210 performs data reception by a receiving method using wired communication, this is not a limitation and wireless data reception can be adopted instead. Further, a configuration can be adopted that receives data directly from the portable terminal 100, i.e., not via the Internet.

The received amount of electrical energy generated data, state of use data and electrical energy used data are stored in memory means 230 in the server.

Based on the received amount of electrical energy generated data, state of use data and electrical energy used data, the point allocation means 220 performs rating processing in accordance with the amount of electrical energy generated, state of use and used electrical energy, and allocates the user points.

Although the point allocation means 220 performs rating by calculation processing based on the various data, thorough consideration must be given not only to power generation by large-scale equipment but also to small-scale power generation by individuals. As the intent of the present invention is directed more toward enabling users to easily take part in the effort to overcome environmental problems, it would be inappropriate to allocate more points for greater amount of electrical energy generated. Moreover, although electrical energy once generated but not used can be sold in a completely different way, the most important issue here is for the electrical energy used to be cleanly generated energy, without considering sale of electrical energy and giving absolutely no thought to purchase of electrical energy. Simple energy conservation overly concerned about avoiding use of electricity is rather apt rather to dampen user motivation to participate in environmental problem solving.

In the present invention, electrical energy produced by solar power generation is, for example, used on the basis of amount of electrical energy generated data, along with attention to state of use and electrical energy used data, so as to perform rating emphasizing the point of staying outside the conventional loop of using resource-consuming electrical energy from fossil fuels. Specifically, when the result of subtracting used electrical energy from amount of electrical energy generated is positive, the positive result is rated and rating is performed in accordance with state of use after the state of use (use time etc.) is assigned a rating. Moreover, in a case where, for example, there is electrical energy being sold through a different route, a configuration can be adopted that performs separate calculation processing and makes a positive rating.

Since one object of the present invention is to encourage electrical energy conservation activity at the individual level, a configuration is adopted that excludes numerical values related to amount of unused electrical energy from the parameters used in the point allocation calculation processing. In other words, a configuration is adopted that subtracts electrical energy charged in the electrical energy accumulator from amount of electrical energy consumed by the portable terminal and, in order to allocate higher points in proportion as the numerical value of the subtraction result is lower, weights it in proportion as the numerical value is lower, and allocates as points a numerical value obtained as a sum or a product of the weighted value and the amount of electrical energy consumed. Specifically, for example, a weighting table is compiled, heavier weighting is performed in proportion as the aforesaid subtraction result is lower (including negative values), and a numerical value obtained as the sum or product of the weighted value and the amount of electrical energy consumed is allocated as points.

For example, when the amount of electrical energy consumed exceeds the amount of electrical energy generated, the points are left unchanged without any addition to or multiplication of the amount of electrical energy consumed. On the other hand, when the amount of electrical energy consumed is lower than the amount of electrical energy generated, the sum or product of the amount of electrical energy consumed and a weighted numerical value is calculated, so that a higher number of points is allocated even if the amount of electrical energy consumed is the same. Moreover, for the same weighted value, a higher number of points can be obtained in proportion as more electrical energy is consumed. The arrangement is such that even when a large amount of electrical energy is consumed, a high evaluation can be obtained insofar as an equivalent amount of electrical energy is generated, because this means that no resources were wasted.

In other words, the system is set up to evaluate not the amount of electrical energy generated but the amount of generated electrical energy used (consumed) and to highly evaluate the fact that a large amount of consumption is accounted for by consumption of a large amount of electrical energy produced by solar power generation. In this regard, the amount of electrical energy consumed by the portable terminal is calculated from electrical energy used data transmitted from the terminal, and electrical energy charged in the electrical energy accumulator can be obtained from the amount of electrical energy generated data.

In line with the basic concept behind this configuration, use of electrical energy charged in a storage battery translates into point allocation, while the calculation/evaluation is done totally independently of the possibility of selling electrical energy, so that the arrangement does not require a large-scale system capable of generating electricity at a salable level. For example, if electrical energy required by a server and that required by a mobile phone, tablet computer or the like are compared, the server will obviously be found to require more, but when the total number of each in Japan or throughout the world is considered, the total amount of electrical energy required by portable terminals is overwhelming greater. Further, considering solar power generation, for example, even though the solar power generation systems installed in portable terminals are small, they can nevertheless contribute a considerable amount of electrical energy owing to the total number of portable terminals. Moreover, taking a global perspective, the fact that the sun is always shining and solar electrical energy being generated somewhere in the world means that the solar power generation rating system according to the present invention continues to operate 24 hours a day, 365 days a year. In other words, energy conservation can be realized widely, on a large scale, and constantly.

In other words, by using photovoltaically generated electrical energy to power portable terminals, energy conservation can be easily achieved to realize reduction of total electrical energy consumption. Being focused on electrical energy saving at such an individual level, the present invention stimulates environmental problem solving activity by allocating points that help maintain user motivation.

Owing to this arrangement, need to consider sale of electrical energy is absolutely eliminated, and although participation by big businesses with large infrastructures is also possible, a system can be configured that rather places priority on individual level electrical energy conservation targeting small and overwhelming numerous terminals.

An embodiment of the present invention can be configured that performs rating processing not only in the rating server 200 but also distributed rating processing in the portable terminal 100. Adoption of this configuration reduces load on the rating server 200 and can also reduce data volume on the Internet and thereby avoid excessive traffic situations.

Specifically, a computer 150 of the portable terminal 100 automatically calculates amount of electrical energy generated by the solar panel 110 and amount of electrical energy consumed by the user. Next, the computer 150 compares the amount of electrical energy generated and the amount of electrical energy consumed, whereupon it automatically judges whether the amount of electrical energy generated is enough to meet the amount of electrical energy consumed. And a configuration is adopted whereby when the amount of electrical energy generated is greater than the amount of electrical energy consumed, the communication unit 140 having transmit-receive capability transmits an automatically calculated remaining amount of electrical energy to the rating server 200 through a communication network such as the Internet.

Further, amount of electrical energy consumed can also be simultaneously included as an automatic judgment factor. The thinking is that total consumption of a maximum amount of generated electrical energy maximizes avoidance of consumption of commercial electrical energy from fossil fuel, so that rating is preferably based on the assumption that large amount of electrical energy generation combined with large amount of consumption should be defined as the subject of the rating.

The solar power generation rating system according to the present invention can be implemented by cloud computing technology using a cloud model. This expands opportunities by structuring the transmission of various data so that the user side is unaware of processing details and simultaneously facilitates development of processing units and programs for performing processing by the portable terminal 100.

### BRIEF EXPLANATION OF THE DRAWINGS

FIG. 1 is a schematic diagram of a solar power generation rating system.

FIG. 2 is a bock diagram of the solar power generation rating system.

### EXPLANATION OF SYMBOLS

1 Solar power generation rating system
100 Portable terminal
110 Solar panel
120 Electrical energy accumulator
130 Consumed power detection and memory unit
132 Detecting means
134 Memory means
140 Communication unit
142 Communication means
150 Computer
200 Rating server
210 Receiving means
220 Point allocation means
230 Memory means

1-3. (canceled)

4. A solar power generation rating system comprising:
a portable terminal having a portable small solar panel to generate solar power, an electrical energy accumulator to store electrical energy generated by the solar panel, a consumed electrical energy detection and memory unit to detect an amount of generated electrical energy stored in the electrical energy accumulator and used electrical energy signifying a state of use, and a communication unit having transmit-receive capability to transmit values measured by the consumed electrical energy detection and memory unit and used electrical energy to outside;
a rating server to receive data from the portable terminal and perform rating processing;
wherein the consumed electrical energy detection and memory unit comprises a detector to detect the state of use of electrical energy stored in the electrical energy accumulator and used electrical energy, and a memory to sequentially store the amount of electrical energy generated by the solar panel, and the state of use of electrical energy and used electrical energy detected by the detector, the communication unit comprises a communicator to establish at least one of wired and wireless communication with the rating server upon detection by the detector and to automatically transmit an amount of electrical energy generated data, a state of electrical energy use data and an electrical energy used data stored in the memory;
the rating server comprises a receiver to automatically receive the amount of electrical energy generated data, the state of use data and the electrical energy used data transmitted from the communicator, and a point allocator to compare the amount of electrical energy generated, the state of use and the used electrical energy, perform rating processing in accordance with comparison results, and allocate commensurate points.

5. The solar power generation rating system according to claim 4, wherein the point allocator subtracts an electrical energy charged in the electrical energy accumulator obtained from the amount of electrical energy generated data from an amount of electrical energy consumed by the portable terminal obtained from the electrical energy used data to allocate points in a reverse proportion to a numerical value of the subtraction result, a higher point is allocated to a lower numerical value; wherein the point allocator weights the numerical value of the subtraction result in proportion to provide a weighted value and perform a rating by calculating a sum or a product of the weighted value and the amount of electrical energy consumed whose resulting numerical value is defined as the points, and allocates the points.

6. A solar power generation rating system comprising:
a portable small solar panel attached to a portable terminal to generate solar power, an electrical energy accumulator to store an electrical energy generated by the solar panel, a consumed electrical energy detection and memory unit to detect an amount of generated electrical energy stored in the electrical energy accumulator and an amount of electrical energy used by the portable terminal, and a communication unit having transmit-receive capability to transmit values measured by the consumed electrical energy detection and memory unit and the amount of electrical energy used to outside;
wherein a computer of the portable terminal automatically calculates an amount of electrical energy generated and an amount of electrical energy consumed, automatically determines following a comparison processing whether the amount of electrical energy generated is enough to meet the amount of electrical energy consumed, and in response to a determination that the amount of electrical energy generated is greater than the amount of electrical energy consumed, the computer uses the communication unit having transmit-receive capability to transmit the automatically calculated remaining amount of electrical energy to the rating server that communicates with the consumed electrical energy detection and memory unit.
